(19) United States
(12) Patent Application Publication
(10) Pub. No.: US 2026/0314486 A1
(43) Pub. Date: Oct. 8, 2026

(54) THREE-DIMENSIONAL CHIP STACK WITH BACKSIDE POWER DISTRIBUTION NETWORK

(71) Applicant: International Business Machines Corporation, Armonk, NY (US)

(72) Inventors: Xiaoli He, Clifton Park, NY (US); Joshua Mark Rubin, Albany, NY (US); Tao Li, Slingerlands, NY (US); Ruilong Xie, Niskayuna, NY (US); Qianwen Chen, Fort Collins, CO (US)

(21) Appl. No.: 19/170,678

(22) Filed: Apr. 4, 2025

(51) Int. Cl. H10W 90/00; H10W 90/28

(52) U.S. Cl. CPC H10W 90/00; H10W 90/28; H10W 90/754; H10W 90/764; H10W 90/792

(57) ABSTRACT

A semiconductor structure is provided which includes a 3D chip stack including a bottom chip and a top chip having a backside power distribution network (BSPDN) in which the top chip is hybrid bonded to the bottom chip and where the top chip and bottom chip are electrically connected to a packaging substrate. The electrical connection can be through a metal wire, a metal clip or any combination thereof.

### BACKGROUND

The present application relates to semiconductor technology, and more particularly to a semiconductor structure including a three dimensional (3D) chip stack including a bottom chip and a top chip having a backside power distribution network (BSPDN) in which the top chip is hybrid bonded to the bottom chip and where the top chip and bottom chip are electrically connected to a packaging substrate.

3D chip stacking is a technique used to manufacture MOS (metal-oxide semiconductor) integrated circuits (ICs) by stacking a plurality of ICs and interconnecting them vertically using, for instance, through-silicon vias (TSVs) or Cu-Cu connections. This technique allows the ICs to behave as a single device, which can lead to performance improvements at reduced power and smaller footprint than conventional two-dimensional processes.

### SUMMARY

A semiconductor structure is provided which includes a 3D chip stack including a bottom chip and a top chip having a BSPDN in which the top chip is hybrid bonded to the bottom chip and where the top chip and bottom chip are electrically connected to a packaging substrate. The electrical connection can be through a metal wire, a metal clip or any combination thereof.

In one embodiment of the present application, the semiconductor structure includes a bottom chip including a semiconductor substrate, a first front-end-of-line (FEOL) level and a first back-end-of-line (BEOL) structure; a top chip including a second FEOL level located between a second BEOL structure and a BSPDN structure, where a hybrid bonding interface is present between the first BEOL structure of the bottom chip and the second BEOL structure of the top chip; and a packaging substrate attached to the semiconductor substrate of the bottom chip, where the top chip and the bottom chip are independently electrically connected to the packaging substrate.

### BRIEF DESCRIPTION OF THE DRAWINGS

FIG. 1 is a cross sectional view of an exemplary structure that can be employed in the present application, the exemplary structure includes a bottom chip (in wafer or diced form), the bottom chip including a semiconductor substrate, a first FEOL level, and a first BEOL structure.

FIG. 2 is a cross sectional view after hybrid bonding a top chip including a second BEOL structure, a second FEOL level, a BSPDN structure and a plurality of external BSPDN metal pads to the exemplary structure illustrated in FIG. 1 to form a 3D chip stack in which the top chip is positioned on top of the bottom chip and a hybrid bonding interface is formed between the second BEOL structure of the top chip and the first BEOL structure of the bottom chip.

FIG. 3 is a cross sectional view of the 3D chip stack of FIG. 2 after attaching the semiconductor substrate of the 3D chip stack to a packaging substrate.

FIG. 4 is a cross sectional view of the 3D chip stack of FIG. 3 after wiring bonding the top chip and the bottom chip to the packaging substrate.

FIG. 5 is a cross sectional view of the 3D chip stack of FIG. 2 after depositing an insulation layer on top of the bottom chip and adjacent to, and above, the top chip.

FIG. 6 is a cross sectional view of the 3D chip stack of FIG. 5 after forming an opening in the insulation layer that physically exposes a metal structure of the first BEOL structure.

FIG. 7 is a cross sectional view of the 3D chip stack of FIG. 6 after attaching the semiconductor substrate of the 3D chip stack to a packaging substrate, and wiring bonding the top chip and the bottom chip to the packaging substrate.

FIG. 8 is a cross sectional view of an exemplary structure that can be employed in the present application, the exemplary structure includes a bottom chip (in wafer or diced form), the bottom chip including a semiconductor substrate, a first FEOL level, and a precursor first BEOL structure containing a wire bond pad.

FIG. 9 is a cross sectional view of the exemplary structure of FIG. 8 after recessing the wire bond pad.

FIG. 10 is a cross sectional view of the exemplary structure of FIG. 9 after forming last level metal wiring in the precursor first BEOL structure to provide a first BEOL structure.

FIG. 11 is a cross sectional view the exemplary structure of FIG. 10 after hybrid bonding a top chip including a second BEOL structure, a second FEOL level, a BSPDN structure and a plurality of external BSPDN metal pads to the exemplary structure illustrated in FIG. 10 to form a 3D chip stack in which the top chip is positioned on top of the bottom chip and a hybrid bonding interface is formed between the second BEOL structure of the top chip and the first BEOL structure of the bottom chip.

FIG. 12 is a cross sectional view of the 3D chip stack of FIG. 11 after depositing an insulation layer on top of the bottom chip and adjacent to, and above, the top chip.

FIG. 13 is a cross sectional view of the 3D chip stack of FIG. 12 after forming an opening in the insulation layer that physically exposes the wire bond pad of the first BEOL structure.

FIG. 14 is a cross sectional view of the 3D chip stack of FIG. 13 after attaching the semiconductor substrate of the 3D chip stack to a packaging substrate, and wiring bonding the top chip and the bottom chip to the packaging substrate.

FIGS. 15A and 15B are cross sectional views illustrated alternative semiconductor structures in accordance with various embodiments of the present application in which at least one metal clip is used instead of a metal wire.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Along with the scaling down trend of the minimum feature size, backside power delivery has emerged as a new feature of advanced technology nodes. Backside power delivery refers to a technique where power supply lines are routed on the backside of a semiconductor chip or integrated circuit (IC), rather than the traditional frontside. Backside power delivery offers several advantages, including increased logic density and improved power and performance (better signal integrity, reduced noise and improved overall chip performance). Also, placing the power lines on the backside can reduce interference with signal paths. The backside power delivery includes a BEOL structure including power lines embedded in one or more interlayer dielectric materials. In the present application, such “backside” BEOL structure is referred to as a backside power distribution network (i.e., BSPDN) structure. 3D packaging of stacked chips with a BSPDN structure is needed for advanced technology nodes.

The present application provides a semiconductor structure including a top chip having a BSPDN bonded to a bottom chip in which the top chip and bottom chip are electrically connected to a packaging substrate. In the semiconductor structure of the present application, hybrid bonding is used to form a 3D chip stack (or chip stack assembly) in which a hybrid bond is formed between a frontside BEOL structure of the top chip and a frontside BEOL structure of the bottom chip. Throughout the present application, the term “hybrid bonding” refers to a 3D packing technique to connect semiconductor builds. Hybrid bonding forms connections of semiconductor structures through metal bond pads which are embedded in a dielectric layer at a bond interface on each semiconductor structure that is being bonded. The dielectric layer at bonding interface includes, but is not necessarily limited to, TEOS, SiO₂, SiCN, and/or SiCOH. The metal bond pads embedded in the dielectric surfaces most commonly include, but are not necessarily limited to, copper (Cu). As part of the hybrid bonding process, the aforementioned dielectric materials go through an activation process, including but not necessarily limited to, O₂/N₂ plasma activation followed by a de-ionized water rinsing. Such activation process creates surface dangling bonds through hydroxylation of dielectric surfaces. Hybrid bonding process itself includes alignment to control the overlay of metal pads and to ensure electrical continuity between semiconductor build undergoing hybrid bonding process, mating of dielectric/metal pad surfaces, annealing under a set pressure. The anneal process of the mated semiconductor builds ensures formation of covalent bonds between the dangling bonds across the dielectric surfaces of opposing semiconductor builds, as well as reflow (melting and joining) of the metal pads between the surfaces of opposing semiconductor builds to ensure electrical conductivity. The covalent bonds formed between the dielectric surfaces, and the joining of metal pads as a result of reflow process ensures that hybrid bonding interfaces joins two semiconductor builds and also ensures that there is electrical continuity between them. The dangling bonds and covalent bonding occurs in the present application.

Notably, and as is illustrated in FIGS. 4, 7, 14, 15A and 15B, a semiconductor structure is provided that includes a bottom chip including semiconductor substrate 12, first FEOL level 14 and first BEOL structure 16; a top chip including second FEOL level 30 located between second BEOL structure 24 and BSPDN structure 32, where a hybrid bonding interface HBI is present between the first BEOL structure 16 of the bottom chip and the second BEOL structure 24 of the top chip; and packaging substrate 42 attached to the semiconductor substrate 12 of the bottom chip, where the top chip and the bottom chip are independently electrically connected to the packaging substrate (e.g., BSPDN structure of the top chip is electrically connected to the package substrate 42 and the first BEOL structure 16 is also electrically connected to the package substrate 42). The electrical connection can be achieved utilizing a metal wire, a metal clip or a combination of a metal wire and a metal clip. The semiconductor structure of the present application including a BSPDN structure with wiring bonding and/or metal clip bonding can provide power delivery optimization for mobile applications and use in future advanced node technology. In the present application the first BEOL structure 16 can be referred to a first frontside BEOL structure, while the second BEOL structure 24 can be referred to a second frontside BEOL structure since both BEOL structures are located on a frontside in their respective chips.

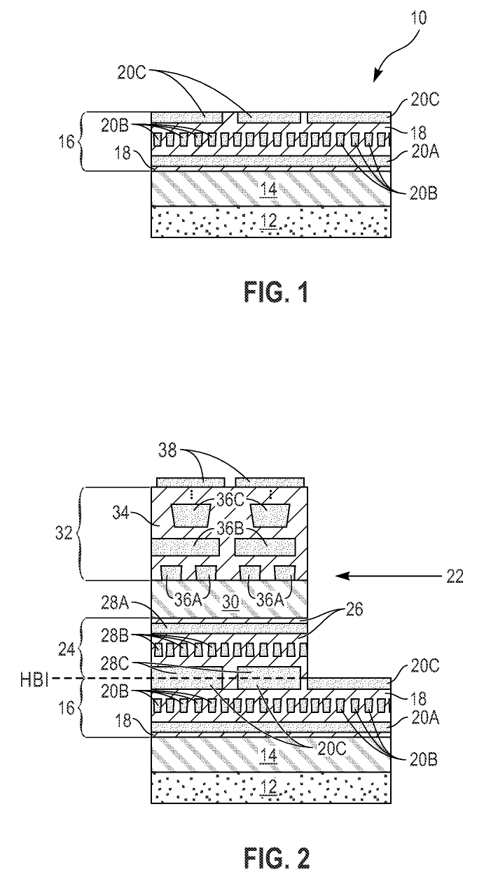

Reference will now be made to FIG. 1 which illustrates an exemplary (or initial) structure 10 that can be employed in the present application. The exemplary structure 10 includes a bottom chip (in wafer or diced form). The exemplary structure 10 can include any number of bottom chips as long as at least one bottom chip is contained in the exemplary structure 10. Each bottom chip includes a semiconductor substrate 12, a first FEOL level 14, and a first BEOL structure 16. In wafer form, a common semiconductor substrate is used as is illustrated in FIG. 1. In diced form, each chip is located on its own semiconductor substrate.

Semiconductor substrate 12 includes at least one semiconductor material having semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments, semiconductor substrate 12 is a bulk substrate that includes a single semiconductor material, or a stack of two or more semiconductor materials. In yet other embodiments, semiconductor substrate 12 is a semiconductor-on-insulator substrate in which a dielectric layer (such as, for example, silicon dioxide and/or boron nitride) is sandwiched between a semiconductor base layer and a semiconductor device layer. the semiconductor base layer and the semiconductor device layer can be composed of a compositionally same semiconductor material (such as, for example, Si), or compositionally different semiconductor materials (such as Si and SiGe).

The first FEOL level 14 includes one or more semiconductor devices such as, for example, transistors, resistors and/or capacitors formed upon semiconductor substrate 12. In one example, the one or more semiconductor devices include at least one transistor (or field effect transistor (FET)). A transistor includes a source region, a drain region, a semiconductor channel region located between the source region and the drain region, and a gate structure in contact with the semiconductor channel region. Collectively, the source region and the drain region can be referred to as a source/drain region. As used herein, a "source/drain" region can be a source region or a drain region depending on subsequent wiring and application of voltages during operation of the transistor. The transistor that can be present in the first FEOL level 14 is not limited to any type of transistor. For example, planar transistors and/or non-planar transistors can be used. In some embodiments and by way of one example, the transistor is a nanosheet transistor (i.e., a non-planar transistor) that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Oher types of transistors that can be employed include finFETs, nanowire FETs, planar transistors, fork sheet transistors, or any combination of such transistors The at least one semiconductor device that is present in the first FEOL level 14 can be formed utilizing any well-known device process that is capable of forming a specific type of device.

Although not illustrated in the drawings, a first middle-of-line (MOL) level can be located between the first FEOL level 14 and the first BEOL structure 16. The first MOL level includes at least one frontside metal contact structure (i.e., a frontside source/drain contact structure and/or a frontside gate contact structure) that are electrically connected to the one or more semiconductor devices. The at least one frontside metal contact structure of the first MOL level is embedded in at least one interconnect dielectric material. The at least one interconnect dielectric material can be located adjacent to, and on top of, the at least one semiconductor device present in the first FEOL level 14. The first MOL level can be formed by a metallization process in which at least one frontside contact opening is formed into a previously deposited interconnect dielectric material layer by lithographic patterning, and thereafter the least one frontside metal contact structure is formed into the at least one frontside contact opening by deposition of an electrically conductive material, followed by a planarization process. In some embodiments, a diffusion barrier liner material containing layer can be deposited into the at least one frontside contact opening prior to depositing and planarizing of the electrically conductive material.

The least one frontside metal contact structure of the first MOL level is composed of an electrically conductive metal or electrically conductive metal alloy (collectively the electrically conductive metal or electrically conductive metal alloy can be referred to as an electrically conductive material). Illustrative examples of electrically conductive materials that can be used in the present application to provide the at least one frontside metal contact structure include, but are not limited to, Cu, Al, Cu-Al alloy, W, Ru, or Rh. In some embodiments, a diffusion barrier liner can be located on a sidewall and along a bottommost surface of the at least one frontside metal contact structure. When present, the diffusion barrier liner is composed of a diffusion barrier material. Exemplary diffusion barrier materials that can be used in providing the diffusion barrier liner include, but are not limited to, Ta, TaN, Ti, TiN, W and/or WN. In some embodiments, the diffusion barrier liner is composed of a single diffusion barrier material. In other embodiments, the diffusion barrier liner is composed of a diffusion barrier material stack of two or more diffusion barrier materials. In one example, the diffusion barrier liner can be composed of a stack of Ta/TaN or a stack of Ti/TiN. The at least one interconnect dielectric material that provides the first MOL level is composed of any interconnect dielectric material including, for example, silicon oxide (SiOₓ), silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The first BEOL structure 16 includes a plurality of first frontside BEOL metal levels embedded in at least one first frontside interlayer dielectric material 18. In the illustrated embodiment, the first BEOL structure 16 includes a first frontside metal level 20A embedded in a lower portion of the at least one first frontside interlayer dielectric material 18, a second frontside metal level 20B embedded in a middle portion of the at least one first frontside interlayer dielectric material 18, and a third frontside metal level 20C embedded in a topmost portion of the at least one first frontside interlayer dielectric material 18. In the illustrated embodiment, the third frontside metal level 20C represents a last frontside metal level of the first BEOL structure 16. In the present application, the plurality of first frontside BEOL metal levels that are present in the first BEOL structure 16 can be interconnected together and can be used to send signals to the one or more devices in the first FEOL level 14. The first BEOL structure 16 can be formed utilizing BEOL process techniques that are well known to those skilled in the art. It is noted that while the present application describes and illustrates three frontside metal levels in the first BEOL structure 16, the present application is not limited to the same. For example, the first BEOL structure 16 can include two frontside metal levels or greater than three frontside metal levels.

The plurality of first frontside BEOL metal levels (including first frontside metal level 20A, the second frontside metal level 20B and the third frontside metal level 20C) include metal structures (i.e., vias, lines or combinations thereof) that can be composed of a compositionally same or compositionally different electrically conductive material as mentioned above. In some embodiments, at least one of the metal structures present in the third frontside metal level 20C (for example, the one of the far right hand side of the exemplary structure 10) is composed of a compositionally different electrically conductive material than the other metal structures present in the third frontside metal level 20C. In some embodiments (not illustrated), a diffusion barrier liner (composed of a diffusion barrier material) as mentioned above can be present along a sidewall and a bottommost surface of each metal structure that is present in the various first frontside BEOL metal levels of the plurality of first frontside BEOL metal levels. The at least one first frontside interlayer dielectric material 18 is composed of an interlayer dielectric material including silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned in this application are measured in a vacuum unless otherwise noted.

Referring now to FIG. 2, there is illustrated a 3D chip stack that is formed after hybrid bonding a top chip including a second BEOL structure 24, a second FEOL level 30, a BSPDN structure 32 and a plurality of external BSPDN metal pads 38 to the bottom chip of exemplary structure 10 illustrated in FIG. 1. In the 3D chip stack that is formed the top chip is positioned on top of the bottom chip and a hybrid bonding interface HBI is formed between the second BEOL structure 24 of the top chip and the first BEOL structure 16 of the exemplary structure 10. Although a single top chip is described and illustrated, a plurality of top chips can be employed in the present application. In such embodiments, multiple top chips can be placed on top of the bottom chip. Attentively, the present application includes an embodiment in which multiple top chips are used in which at least some of the top chips straddle more than one bottom chip.

The second FEOL level 30 of the top chip includes one or more semiconductor devices such as, for example, transistors, resistors and/or capacitors formed upon semiconductor substrate which is entirely or partially removed during the formation of the BSPDN structure 32. In one example, the one or more semiconductor devices of the second FEOL level 30 include at least one transistor as defined above. In the present application, the second FEOL level 30 includes a frontside in which the second BEOL structure 24 is located therein, and a backside (opposite the frontside) in which BSPDN structure 32 is located therein.

Although not illustrated in the drawings, a second MOL level can be located between the second FEOL level 30 and the second BEOL structure 24. The second MOL level includes at least one frontside metal contact structure (i.e., a frontside source/drain contact structure and/or a frontside gate contact structure) that are electrically connected to the one or more semiconductor devices of the second FEOL level 30. The at least one frontside metal contact structure of the second MOL level is embedded an at least one interconnect dielectric material. The at least one interconnect dielectric material can be located adjacent to, and on top of, the at least one semiconductor device present in the second FEOL level 30. The second MOL level can be formed by a metallization process as mentioned above. The least one frontside metal contact structure of the second MOL level is composed of an electrically conductive material as mentioned above. In some embodiments, a diffusion barrier liner can be located on a sidewall and along a bottommost surface of the at least one frontside metal contact structure. When present, the diffusion barrier liner is composed of a diffusion barrier material as mentioned above. The at least one interconnect dielectric material that provides the second MOL level is composed of an interconnect dielectric material as mentioned above.

The second BEOL structure 24 includes a plurality of second frontside BEOL metal levels embedded in at least one second frontside interlayer dielectric material 26. In the illustrated embodiment, the second BEOL structure 24 includes a first frontside metal level 28A embedded in a lower portion of the at least one second frontside interlayer dielectric material 26, a second frontside metal level 28B embedded in a middle portion of the at least one second frontside interlayer dielectric material 26, and a third frontside metal level 28C embedded in a topmost portion of the at least one second frontside interlayer dielectric material 26. In the illustrated embodiment, the third frontside metal level 28C represents a last frontside metal level of the second BEOL structure 24. In the present application, the plurality of second frontside BEOL metal levels that are present in the second BEOL structure 24 can be interconnected together and can be used to send signals to the one or more devices in the second FEOL level 30; these signals can ultimately be sent to the one of more devices present in the first FEOL level 14 through the metal structure present in the first BEOL structure 16. The second BEOL structure 24 can be formed utilizing BEOL process techniques that are well known to those skilled in the art. It is noted that while the present application describes and illustrates three frontside metal levels in the second BEOL structure 24, the present application is not limited to the same. For example, the second BEOL structure 24 can include two frontside metal levels or greater than three frontside metal levels.

The plurality of second frontside BEOL metal levels (including first frontside metal level 28A, the second frontside metal level 28B and the third frontside metal level 28C) include metal structure that are composed of a compositionally same or compositionally different electrically conductive material as mentioned above. In some embodiments (not illustrated), a diffusion barrier liner (composed of a diffusion barrier material) as mentioned above can be present along a sidewall and a bottommost surface of each metal structure of each second frontside BEOL metal level of the plurality of second frontside BEOL metal levels. The at least one second frontside interlayer dielectric material 26 is composed of an interlayer dielectric material as mentioned above.

The BSPDN structure 32 includes a plurality of BSPDN metal levels and at least one BSPDN interlayer dielectric material 34. In the illustrated embodiment, the BSPDN structure 32 includes a first BSPDN metal level 36A embedded in a first portion of the at least one BSPDN interlayer dielectric material 34, a second BSPDN metal level 36B embedded in a second portion of the at least one BSPDN interlayer dielectric material 34, and a third BSPDN metal level 36C embedded in a third portion of the at least one BSPDN interlayer dielectric material 34. In the illustrated embodiment, a plurality of external BSPDN metal pads 38 are present on a topmost surface of the BSPDN structure 32. In the present application, the plurality of BSPDN metal levels that are present in the BSPDN structure 32 can be interconnected together and can be used to send power to the one or more devices present in the 3D chip stack. The BSPDN structure 32 can be formed utilizing backside BSPDN process techniques that are well known to those skilled in the art. The external BSPDN metal pads 38 can be in electrically contact with the plurality of BSPDN metal levels that are present in the BSPDN structure 32. The external BSPDN metal pads 38 can be formed prior to, or after, the hybrid bonding processing using techniques well known in the art. Typically, the external BSPDN metal pads 38 are formed prior to performing the hybrid bonding process. In some embodiments, a damascene process can be used in forming the external BSPDN metal pads 38. In other embodiments, a subtractive process (which includes deposition of a metal pad material and etching) can be used in forming the external BSPDN metal pads 38. The external BSPDN metal pads 38 can be composed of Al, NiPd, Ni, Pd, or other metals that are alloys (e.g., Al-Cu) and capped with Au. Furthermore, and although not depicted in the drawings, the external BSPDN metal pads 38 could have a passivation layer extending partially over each of the external BSPDN metal pads 38 with openings for future wire bonding. Exemplary passivation layers include, but are not limited to: SiO₂, SiN or organic passivation films.

The plurality of BSPDN metal levels (including first BSPDN metal level 38A, the second BSPDN metal level 38B and the third BSPDN metal level 38C) and the external BSPDN metal pads 38 include metal structures that are composed of a compositionally same or compositionally different electrically conductive material as mentioned above. In some embodiments (not illustrated), a diffusion barrier liner (composed of a diffusion barrier material) as mentioned above can be present along a sidewall and a bottommost surface of each of the metal structures that provide the plurality of BSPDN metal levels. The at least one BSPDN interlayer dielectric material 34 is composed of an interlayer dielectric material as mentioned above.

In the present application, the top chip is formed from a semiconductor wafer that is processed utilizing conventional frontside and backside BSPDN processing techniques and thereafter the wafer is diced into individual chips. After dicing, the top chip is hybrid bonded to the exemplary structure 10 shown in FIG. 1 to provide the 3D chip stack illustrated in FIG. 2. Hybrid bonding includes flipping the second chip such that the second BEOL structure 24 of the top chip faces the first BEOL structure 16 of bottom chip. After flipping, the second chip is aligned over bottom chip such that each individual metal structure present in the third frontside metal level 28C of the second BEOL structure 24 is aligned over a corresponding individual metal structure present in the third frontside metal level 20C of the first BEOL structure 16. After alignment, the top chip and the exemplary structure 10 are brought into intimate contact with each other. The bringing the aligned top chip into intimate contact with the bottom chip of can include the application of an external force which may or may not remain during the heating step. After aligning and contacting, the hybrid bonding process continues by heating the aligned and contacted structure from room temperature (i.e., 20°C-25°C) up to 450°C; temperatures greater than 450°C can also be used in the present application. The heating step is typically performed in an inert ambient such as, for example, He, Ar, Ne or mixtures thereof. The heating steps bonds the top chip to the exemplary structure 10 and provides a hybrid bonding interface HBI between the top chip and the bottom chip. After bonding, the temperature can be lowered back to room temperature. The hybrid bonding process can also include an activation process as described above.

At the hybrid bonding interface HBI, bonding occurs between the second BEOL structure 24 and the first BEOL structure 16. Notably, a HBI is formed between metal structures present in the third frontside metal level 28C of the second BEOL structure 24 and corresponding metal structures present in the third frontside metal level 20C of the first BEOL structure 16; the HBI is also formed between the at least one second frontside interlayer dielectric material 26 and the at least one first frontside interlayer dielectric material 18. Notably, a metal-to-metal bond forms between the metal structures present in the third frontside metal level 28C of the second BEOL structure 24 and corresponding metal structures present in the third frontside metal level 20C of the first BEOL structure 16. In the illustrated embodiment of the present application, at least one of the metal structures of third frontside metal level 20C of the first BEOL structure 16 is not hybrid bonded to an overlying metal structure of the third frontside metal level 28C of the second BEOL structure 24. This metal-to-metal bond electrically connects the top chip to the bottom chip at the hybrid bonding interface. A dielectric-to-dielectric bond is also formed between the at least one second frontside interlayer dielectric material 26 and the at least one first frontside interlayer dielectric material 18.

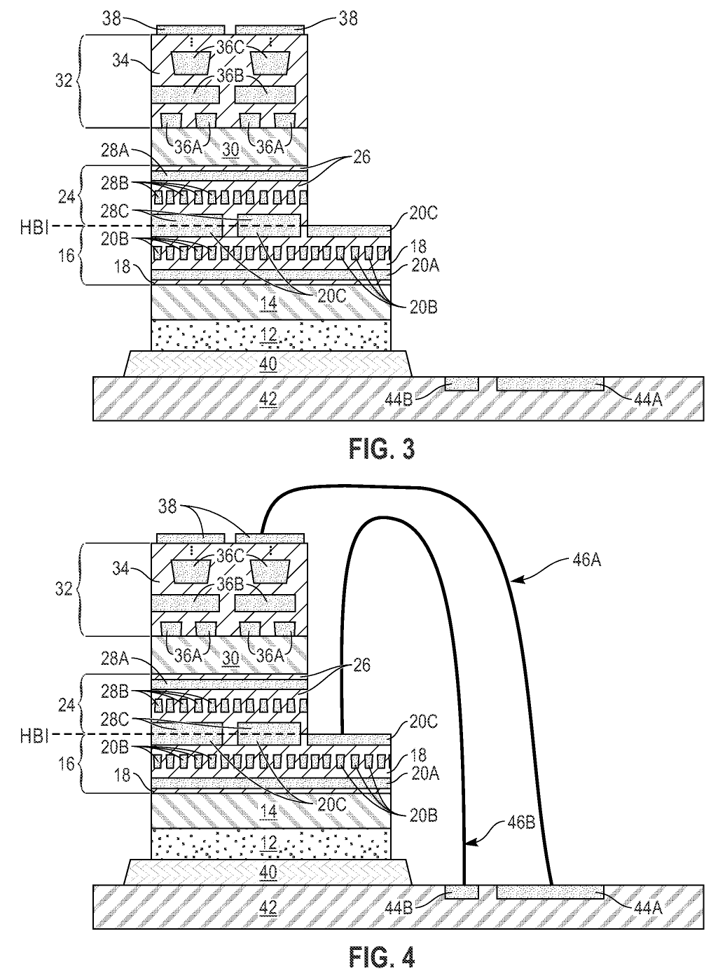

Referring now to FIG. 3, there is illustrated the 3D chip stack of FIG. 2 after attaching the semiconductor substrate 12 of the 3D chip stack to a packaging substrate 42. In some embodiments of the present application, an adhesive (such as, for example, an epoxy) is applied to the backside of semiconductor substrate 12 and is used as an attachment structure 40 for attaching the 3D chip structure illustrated in FIG. 2 to packaging substrate 42. In other embodiments, attachment structure 40 can include a thermal bond pad or a solder pad; in such embodiments heat dissipation from the 3D chip stack through the semiconductor substrate 12 can occur. The packaging substrate 42 includes any conventional packaging substrate that includes at least a first packaging bond pad 44A and a second packaging bond pad 44B present within or on a surface of the packaging substrate 42. The first packaging bond pad 44A and the second packaging bond pad 44B are composed of a bond pad material such as, for example, an electrically conductive material (e.g., Cu) as mentioned above. As is illustrated, the 3D chip stack illustrated in FIG. 2 is attached to the packaging substrate 42 such that the first packaging bond pad 44A and the second packaging bond pad 44B are physically exposed.

Referring now to FIG. 4, there is illustrated the 3D chip stack of FIG. 3 after wiring bonding the top chip and the bottom chip to the packaging substrate 42. In one embodiment and as illustrated in FIG. 4, the wiring bonding includes forming a first metal wire 46A having a first end in contact with one of the external BSPDN metal pads 38 that is located on the BSPDN structure 32 and a second end in contact with the first packaging bond pad 44A, and a second metal wire 46B having a first end in contact with one of the metal structures present in third frontside metal level 20C of the first BEOL structure 16 and a second end in contact with the second packaging bond pad 44B, The first metal wire 46A and second metal wire 46B are composed conventional electrically conductive metals, and are wiring bonded utilizing techniques well known to those skilled in the art. In some embodiments not illustrated, an encapsulation can be located over each of the metal wires. Also, an epoxy or molding compound can be used to provide improved reliability. Although FIG. 4 illustrates wiring bonding at a single edge of the 3D chip stack, the present application contemplates embodiments in which wiring bonding can occur at multiple edges of the 3D chip stack. Hence, and this embodiment, wiring bonding is performed on at least one edge of the 3D chip stack.

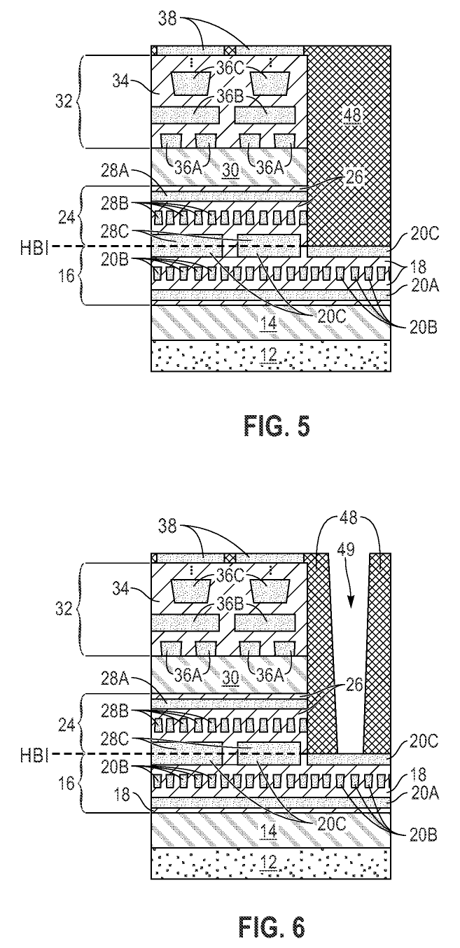

Referring now to FIG. 5, there is illustrated the 3D chip stack of FIG. 2 after depositing an insulation layer 48 on top of the bottom chip and adjacent to, and above, the top chip. It is noted that although insulation layer 48 is described and illustrated as s single layer, the present application contemplates embodiments which multiple insulation layers can be employed in place of insulation layer 48. The insulation layer 48 includes an interlayer dielectric material that can be compositionally the same as, or compositionally different from the interlayer dielectric material that provides the at least one second frontside interlayer dielectric material 26 and/or the at least one BSPDN interlayer dielectric material 34. The insulation layer 48 can be formed by a deposition process such as, for example, chemical vapor deposition (CVD), plasma enhanced chemical vapor deposition (PECVD) or spin-on coating, followed by a planarization process such as, for example, chemical mechanical planarization (CMP). The insulation layer 48 is formed on top of one of the metal structures of the third frontside metal level 20C of the first BEOL structure 16 that is not hybrid bonded to an overlying metal structure of the third frontside metal level 28C of the second BEOL structure 24 and along at least one edge of the top chip. The insulation layer 48 is formed between each of the external BSPDN metal pads 38 that is located on the BSPDN structure 32. The topmost surface of each external BSPDN metal pad 38 remains physically exposed. It should be noted that all of this processing may be taking place in a wafer format, such that the dies at bonded to a wafer, and then insulation layer 48 is formed.

Referring now to FIG. 6, there is illustrated the 3D chip stack of FIG. 5 after forming an opening 49 in the insulation layer 48 that physically exposes one of the metal structure of the first BEOL structure 16. Notably, opening 49 physically exposes the at least one metal structure of the third frontside metal level 20C of the second BEOL structure 24 that is not hybrid bonded to an overlying metal structure of the third frontside metal level 28C of the second BEOL structure 24. Opening 49 can be formed by photolithographic patterning process in which a patterned photoresist and etching are employed. The etch used in the photolithographic patterning process stops on a surface of one of the metal structures of the third frontside metal level 20C of the first BEOL structure 16 that is not hybrid bonded to an overlying metal structure of the third frontside metal level 28C of the second BEOL structure 24.

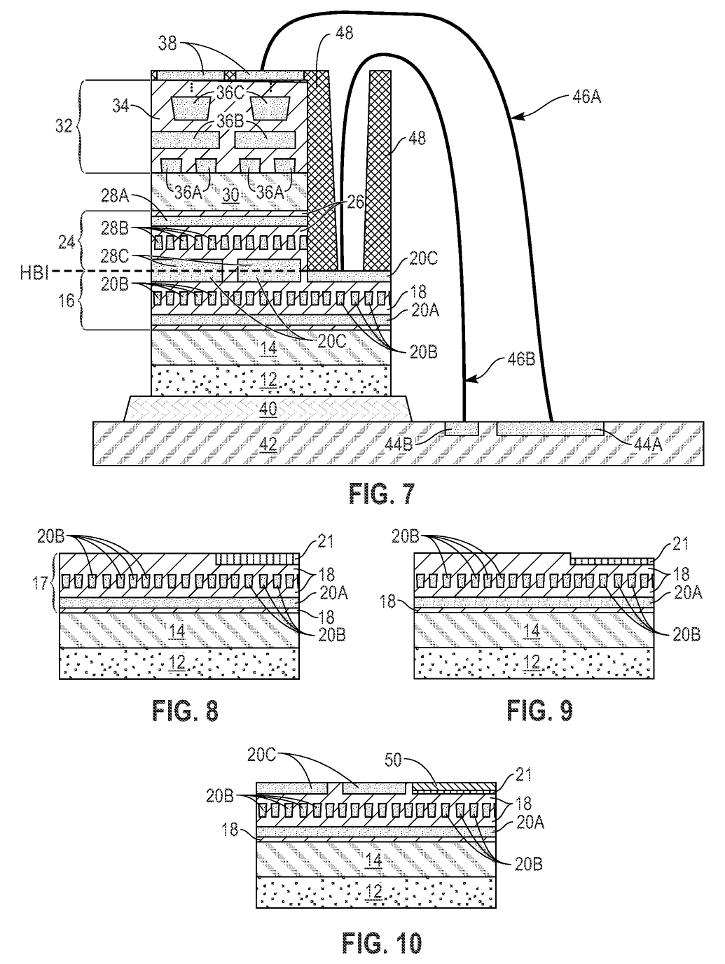

Referring now to FIG. 7, there is illustrated the 3D chip stack of FIG. 6 after attaching the semiconductor substrate 12 of the 3D chip stack to packaging substrate 42, and wiring bonding the top chip and the bottom chip to the packaging substrate 42. In some embodiments of the present application, an adhesive (such as, for example, an epoxy) is applied to the backside of semiconductor substrate 12 and is used as an attachment structure 40 for attaching the 3D chip structure illustrated in FIG. 6 to packaging substrate 42. In other embodiments, the attachment structure 40 can include a thermal pad or a solder pad. The packaging substrate 42 includes any conventional packaging substrate that includes at least a first packaging bond pad 44A and a second packaging bond pad 44B present within or on a surface of the packaging substrate 42. The first packaging bond pad 44A and the second packaging bond pad 44B are composed of a bond pad material such as, for example, an electrically conductive material as mentioned above. As is illustrated, the 3D chip stack illustrated in FIG. 6 is attached to the packaging substrate 42 such that the first packaging bond pad 44A and the second packaging bond pad 44B are physically exposed.

After attaching the 3D chip stack to packaging substrate 42, wiring bonding of the top chip and the bottom chip to the packaging substrate 42 is performed. In one embodiment and as illustrated in FIG. 7, the wiring bonding includes forming a first metal wire 46A having a first end in contact with one of the external BSPDN metal pads 38 that is located on top of the BSPDN structure 32 and a send end in contact with the first packaging bond pad 44A, and a second metal wire 46B having a first end in contact with one of the metal structures present in third frontside metal level 20C of the first BEOL structure 16 and a second end in contact with the second packaging bond pad 44B, The first metal wire 46A and the second metal wire 46B are as defined above. Although FIG. 7 illustrates wiring bonding at a single edge of the 3D chip stack, the present application contemplates embodiments in which wiring bonding can occur at multiple edges of the 3D chip stack. Hence, and this embodiment, wiring bonding is performed on at least one edge of the 3D chip stack.

Referring now to FIG. 8, there is illustrated an exemplary structure that can be employed in the present application, the exemplary structure 10 includes a bottom chip (in wafer or diced form), the bottom chip including semiconductor substrate 12, a first FEOL level 14, and a precursor first BEOL structure 17 containing a wire bond pad 21. In this embodiment, the semiconductor substrate 12 and the first FEOL level 14 are the same as described above for the exemplary structure illustrated in FIG. 1. The precursor first BEOL structure 17 is similar to the first BEOL structure 16 illustrated in FIG. 1 in that includes a plurality of first frontside BEOL metal levels (namely, first frontside metal level 20A and the second frontside metal level 20B) embedded in the at least one first frontside interlayer dielectric material 18. The precursor first BEOL structure 17 differs from the first BEOL structure 16 illustrated in FIG. 1 in that it includes wire bond pad 21 and no third frontside metal level 20C. The wire bond pad 21 includes Al, Au or any other electrically conductive material. The wire bond pad 21 can be formed utilizing a metallization process as mentioned above. In some embodiments, the wire bond pad 21 can be formed utilizing a subtractive etching process in which a layer of the wire bond pad material is first deposited and then patterned by lithography and etching to provide the wire bond pad 21. Interlayer dielectric material can then be formed adjacent to the wire bond pad 21 by deposition, followed by a planarization process. The interlayer dielectric material that is formed adjacent to the wire bond pad 21 becomes an upper portion of the at least one first frontside interlayer dielectric material 18. At this point of the present application, the wire bond pad 21 has a topmost surface that is substantially coplanar with a topmost surface of the at least one first frontside interlayer dielectric material 18.

Referring now to FIG. 9, there is illustrated the exemplary structure of FIG. 8 after recessing the wire bond pad 21. In some embodiments, the recessing of the wire bond pad 21 can be omitted. In embodiments in which recessing of the wire bond pad 21 occurs, the recessing includes an etching process. The etching process can include, for example, a reactive ion etch or a wet etching process. The etching process reduces the height of the wire bond pad 21 such that the wire bond pad 21 that is subjected to the recessing has a height that is less than a height of the wire bond pad 21 that was initially formed. In the illustrated embodiment, the wire bond pad 21 after recessing has a topmost surface that is below a topmost surface of the at least one first frontside interlayer dielectric material 18.

Referring now to FIG. 10, there is illustrated the exemplary structure of FIG. 9 after forming last level metal wiring (namely the third frontside metal level 20C) in the precursor first BEOL structure 17 to provide a first BEOL structure 16 of the bottom chip. The third frontside metal level 20C includes metal structures that are composed of an electrically conductive material as mentioned above. The metal structures of the third frontside metal level 20C are composed of an electrically conductive material that can be compositionally the same as, or compositionally different, from the wire bond pad 21. In one exemplary embodiment, the metal structures of the third frontside metal level 20C are composed of Cu, while the wire bond pad 21 is composed of Al or Au. The metal structures that provide the third frontside metal level 20C is formed utilizing a metallization process as mentioned above. The metal structures that provide the third frontside metal level 20C can have a topmost surface that is coplanar with, or slightly above, a topmost surface of the wire bond pad 21; stated in other terms the wire bond pad 21 can have a same or different height than the metal structures that provide the third frontside metal level 20C. In some embodiments, a protective layer 50 is formed on top of the wire bond pad 21 prior to forming the metal structures that provide the third frontside metal level 20C. The forming of the protective layer 50 can be omitted in some embodiments of the present application. The protective layer 50 is composed of a dielectric material that can be compositionally the same as, or compositionally different from the uppermost portion of the at least one first frontside interlayer dielectric material 18 that provides the precursor first BEOL structure 17. The protective layer 50 is formed by a deposition process, followed by a planarization process. The protective layer 50 is typically formed prior to forming the metal structures that provide the third frontside metal level 20C. In the illustrated embodiment, each of the metal structures that provide the third frontside metal level 20C has a topmost surface that is greater than a topmost surface of the wire bond pad 21. In other embodiments, each of the metal structures that provide the third frontside metal level 20C have a top surface that is coplanar with a topmost surface of the wire bond pad 21.

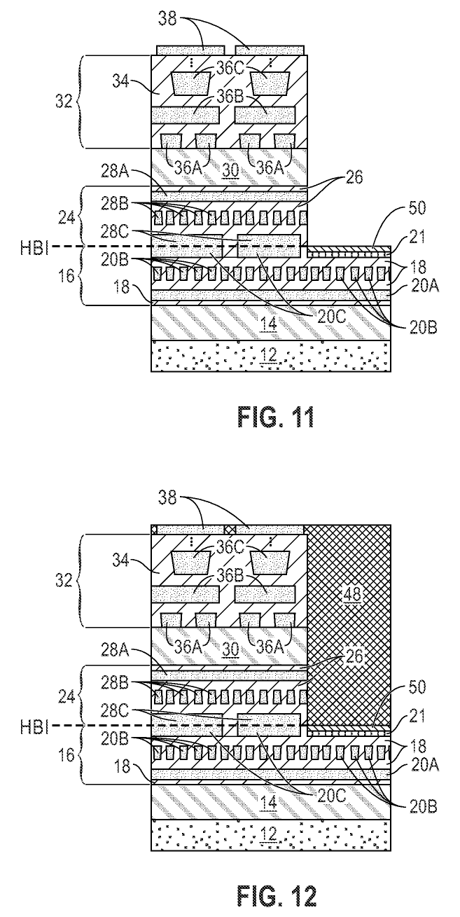

Referring now to FIG. 11, there is illustrated the exemplary structure of FIG. 10 after hybrid bonding a top chip including second BEOL structure 24, second FEOL level 30, BSPDN structure 32 and external BSPDN metal pads 38 to the exemplary structure illustrated in FIG. 10 to form a 3D chip stack in which the top chip is positioned on top of the bottom chip and a hybrid bonding interface HBI is formed between the second BEOL structure 24 of the top chip and the first BEOL structure 16 of the bottom chip. The second BEOL structure 24, the second FEOL level 30 and the BSPDN structure 32 for the top chip are the same as described above for the top chip described in FIG. 2. The hybrid bonding process of this embodiment is the same as that described above for the hybrid bonding process illustrated in FIG. 2.

At the hybrid bonding interface HBI, bonding occurs between the second BEOL structure 24 and the first BEOL structure 16. Notably, a HBI is formed between metal structures present in the third frontside metal level 28C of the second BEOL structure 24 and corresponding metal structures present in the third frontside metal level 20C of the first BEOL structure 16; the HBI is also formed between the at least one second frontside interlayer dielectric material 26 and the at least one first frontside interlayer dielectric material 18. Notably, a metal-to-metal bond forms between the metal structures present in the third frontside metal level 28C of the second BEOL structure 24 and corresponding metal structures present in the third frontside metal level 20C of the first BEOL structure 16. In the illustrated example, the wire bond pad 21 is not hybrid bonded to an overlying metal structure of the third frontside metal level 28C of the second BEOL structure 24. The metal-to-metal bond electrically connects top chip to the bottom chip at the hybrid bonding interface. A dielectric-to-dielectric bond is also formed between the at least one second frontside interlayer dielectric material 26 and the at least one first frontside interlayer dielectric material 18.

In some embodiments (not shown), and opening can be formed into the protective layer 50, then the semiconductor substrate 12 of the 3D chip stack is attached to packaging substrate 42 by an adhesive, thermal pad, solder pad or other like attachment structure 40, and thereafter wiring bonding as described above for the embodiment illustrated in FIG. 4 is performed.

Referring now to FIG. 12, there is illustrated the 3D chip stack of FIG. 11 after depositing insulation layer 48 on top of the bottom chip and adjacent to, and above, the top chip. The insulation layer 48 of this embodiment is the same as that described above in the embodiment illustrated in FIG. 5. It is noted that all this processing may be performed before attachment to packaging substrate 42.

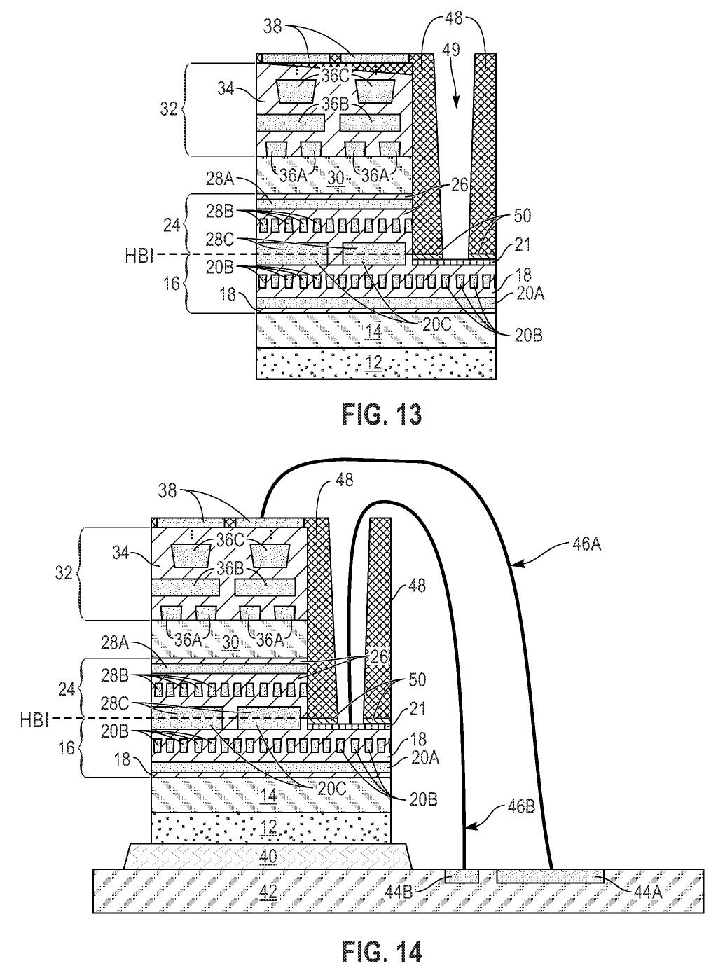

Referring now to FIG. 13, there is illustrated the 3D chip stack of FIG. 12 after forming an opening 49 in the insulation layer 48 that physically exposes the wire bond pad 21 of the first BEOL structure 16. In this embodiment, the opening 49 extends through the insulation layer 48 and through the protective layer 50 (if the same is present) so as to physically expose the wire bond pad 21. Opening 49.can be formed utilizing a photolithography patterning process as mentioned above for forming opening 49 into the insulation layer 48 in the previous embodiment illustrated in FIG. 6 of the present application. In some embodiments, openings 49 can be formed utilizing a laser etching process.

Referring now to FIG. 14, there is illustrated the 3D chip stack of FIG. 13 after attaching the semiconductor substrate 12 of the 3D chip stack to packaging substrate 42, and wiring bonding the top chip and the bottom chip to the packaging substrate 42. In some embodiments of the present application, an adhesive (such as, for example, an epoxy) is applied to the backside of semiconductor substrate 12 and is used as an attachment structure 40 for attaching the 3D chip structure illustrated in FIG. 13 to packaging substrate 42. In other embodiments, attachment structure 40 can include a thermal pad or a solder pad. The packaging substrate 42 includes any conventional packaging substrate that includes at least a first packaging bond pad 44A and a second packaging bond pad 44B present within or on a surface of the packaging substrate 42. The first packaging bond pad 44A and the second packaging bond pad 44B are composed of a bond pad material such as, for example, an electrically conductive material as mentioned above. As is illustrated, the 3D chip stack illustrated in FIG. 14 is attached to the packaging substrate 42 such that the first packaging bond pad 44A and the second packaging bond pad 44B are physically exposed.

After attaching the 3D chip stack to packaging substrate 42, wiring bonding of the top chip and the bottom chip to the packaging substrate 42 is performed. In one embodiment and as illustrated in FIG. 14, the wiring bonding includes forming a first metal wire 46A having a first end in contact with one of the external BSPDN metal pads 38 that is located on top of the BSPDN structure 32 and a second end in contact with the first packaging bond pad 44A, and a second metal wire 46B having a first end in contact with the wire bond pad 21 of the first BEOL structure 16 and a second end in contact with the second packaging bond pad 44B, Although FIG. 14 illustrates wiring bonding at a single edge of the 3D chip stack, the present application contemplates embodiments in which wiring bonding can occur at multiple edges of the 3D chip stack. Hence, and this embodiment, wiring bonding is performed on at least one edge of the 3D chip stack.

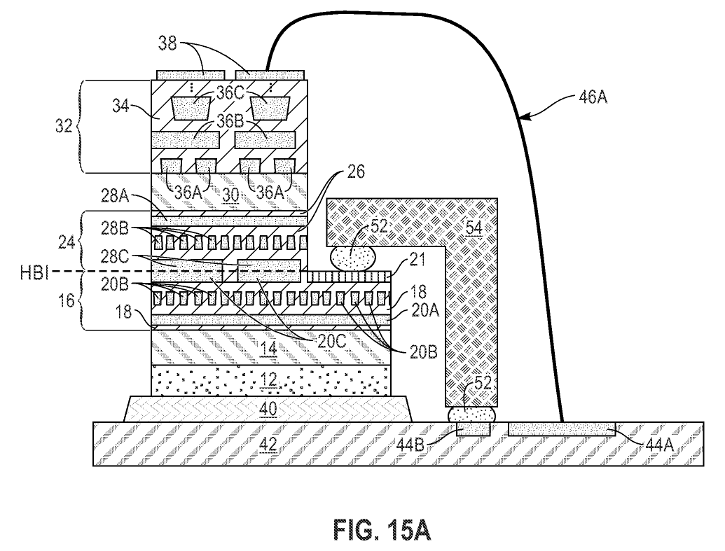

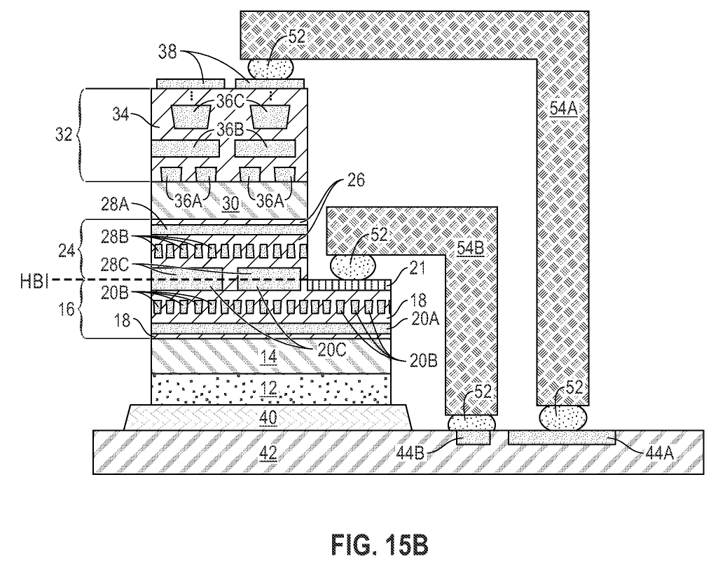

Referring now to FIGS. 15A and 15B, there are illustrated alternative semiconductor structures in accordance with various embodiments of the present application in which at least one metal clip is used instead of a metal wire. The semiconductor structures illustrated in FIGS. 15A -15B include a 3D chip stack similar to the one depicted in FIG. 11 except that no protective layer 50 is present on top of the wire bond pad 21 of the bottom chip. The semiconductor substrate 12 of 3D chip stack of each of the semiconductor structures illustrated in FIGS. 15A-15B is attached to package substrate 42 by attachment structure 40. The attachment structure 40 can be an adhesive, thermal pad or solder pad as mentioned previously herein. The semiconductor structure illustrated in FIG. 15A includes a first metal wire 46A having a first end in contact with one of the external BSPDN metal pads 38 that is present on top of the BSPDN structure 32 and a second end in contact with the first packaging bond pad 44A, and a metal clip 54 having a first end in contact with the wire bond pad 21 and a second end in contact with the first packaging bond pad 44A. The metal clip 54 is composed of an electrically conductive material and the metal clip can be attached utilizing solder ball 52 that is located at both ends of the metal clip 54.

The semiconductor structure illustrated in FIG. 15B is similar to the one illustrated in FIG. 15A except that the first metal wire 46A is replaced with a first metal clip 54A, and the metal clip 54 is replaced with a second metal clip 54B. The semiconductor structure illustrated in FIG. 15B includes a first metal clip 54A in contact with one of the external BSPDN metal pads 38 that is present on top of the BSPDN structure 32 and with the first packaging bond pad 44A, and a second metal clip 54B in contact with the wire bond pad 21 and with the first packaging bond pad 44A. The first and second metal clips are composed of an electrically conductive material and the metal clips can be attached utilizing solder balls 52. Notably, a solder ball 52 that is located at both ends of the first metal clip 54A and at both ends of the second metal clip 54B. In some embodiments, the metal clips are independent between the top chip and the lower chip, while in other embodiments the metal clips are merged. It is noted that the present application works with the permutation in which the bottom chip has a wire bond and the top chip has the metal clip. Furthermore, the present application, contemplates embodiments in which the bottom chip and/or the upper chip could have a combination of chips plus wire bonds so that a given chip is not exclusively one or the other.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a bottom chip comprising a semiconductor substrate, a first front-end-of-line (FEOL) level and a first back-end-of-line (BEOL) structure;
a top chip comprising a second FEOL level located between a second BEOL structure and a backside power distribution network (BSPDN) structure, wherein a hybrid bonding interface is present between the first BEOL structure of the bottom chip and the second BEOL structure of the top chip; and
a packaging substrate attached to the semiconductor substrate of the bottom chip, wherein the top chip and the bottom chip are independently electrically connected to the package substrate.

2. The semiconductor structure of claim 1, wherein the top chip is electrically connected to the packaging substrate utilizing a first metal wire, and the bottom chip is electrically connected to the packaging substrate utilizing a second metal wire.

3. The semiconductor structure of claim 1, wherein the top chip is electrically connected to the packaging substrate utilizing a first metal clip and the bottom chip is electrically connected to the packaging substrate utilizing a second metal clip.

4. The semiconductor structure of claim 1, wherein the top chip is electrically connected to the packaging substrate utilizing a metal wire and the bottom chip is electrically connected to the packaging substrate utilizing a metal clip.

5. The semiconductor structure of claim 1, wherein the top chip comprises an external BSPDN bond pad that is electrically connected to a first packaging bond pad present in, or on, the packaging substrate, and the bottom chip comprises a metal structure present in an upper portion of the first BEOL structure that is electrically connected to a second packaging bond pad present in, or on, the packaging substrate.

6. The semiconductor structure of claim 5, wherein the metal structure is present beneath an insulation layer that is located adjacent to the top chip, and above the bottom chip, and a wire bond passes through the insulation layer and electrically connects the bottom chip to the top chip.

7. The semiconductor structure of claim 1, wherein the top chip comprises an external BSPDN bond pad that is electrically connected to a first packaging bond pad present in, or on, the packaging substrate, and the bottom chip comprises a wire bond pad present in an upper portion of the first BEOL structure that is electrically connected to a second packaging bond pad present in, or on, the packaging substrate.

8. The semiconductor structure of claim 7, wherein the wire bond pad is present beneath an insulation layer that is located adjacent to the top chip and above the bottom chip, and a wire bond passes through the insulation layer and electrically connects the bottom chip to the top chip.

9. The semiconductor structure of claim 7, wherein the wire bond pad is located adjacent to a metal structure present in the upper portion of the first BEOL structure, wherein the metal structure is present at the hybrid bonding interface.

10. The semiconductor structure of claim 9, wherein the wire bond pad has a topmost surface that is coplanar with a topmost surface of the metal structure.

11. The semiconductor structure of claim 9, wherein the wire bond pad has a topmost surface that is lower than a topmost surface of the metal structure.

12. The semiconductor structure of claim 9, wherein the wire bond pad is composed of a compositionally different electrically conductive material than the metal structure.

13. The semiconductor structure of claim 9, further comprises a protective layer located on a topmost surface of the wire bond pad.

14. The semiconductor structure of claim 1, wherein the hybrid bonding interface comprises a metal-to-metal bond and a dielectric-to dielectric bond.

15. The semiconductor structure of claim 1, wherein the bottom chip is in wafer form.

16. The semiconductor structure of claim 1, wherein the bottom chip is in diced form.

17. The semiconductor structure of claim 1, wherein the semiconductor substrate is attached to the packaging substrate by an attachment structure.

18. The semiconductor structure of claim 17, wherein the attachment structure is an adhesive, a thermal bond pad or a solder pad.
